(19) United States
(12) Patent Application Publication
(10) Pub. No.: US 2026/0251617 A1
(43) Pub. Date: Aug. 27, 2026

(54) PROCESSING CHAMBERS FOR CLEANING AND INSPECTION OF BONDED SUBSTRATES AND RELATED METHODS

(71) Applicant: Applied Materials, Inc., Santa Clara, CA (US)

(72) Inventors: Shaowei FU, Singapore (SG); Raymond HUNG, Singapore (SG)

(21) Appl. No.: 19/062,374

(22) Filed: Feb. 25, 2025

(51) Int. Cl. G01N 29/04; G01N 29/28; H10P 72/00

(52) U.S. Cl. CPC G01N 29/043; G01N 29/28; H10P 72/0414; G01N 2291/044; G01N 2291/2697

(57) ABSTRACT

An embodiment of a processing chamber includes an enclosure defining a processing volume, a substrate support positioned in the processing volume to support a substrate and to rotate the substrate about a central axis. In addition, the processing chamber includes a cleaning nozzle to direct a cleaning fluid onto a surface of the substrate within the processing volume. Further, the processing chamber includes an acoustic inspection assembly positioned in the processing volume, the acoustic inspection assembly including a fluid nozzle to direct a stream of fluid onto the surface of the substrate and an acoustic probe coupled to the fluid nozzle such that the acoustic probe is configured to direct an acoustic wave through the stream of fluid to detect a defect in the substrate.

### BACKGROUND

### FIELD

This disclosure relates to processing chambers used in the manufacture of semiconductor devices. More particularly, this disclosure relates to processing chambers and related methods for cleaning and inspecting bonded semiconductor devices.

### DESCRIPTION OF THE RELATED ART

The manufacturing of a semiconductor device includes a number of steps that ultimately conclude with a packaging process that allows the completed semiconductor device to be coupled to or within an electronic device or system. Cleaning and inspection may be performed during or before the packaging process in order to ensure the functionality of the resulting semiconductor devices. Cleaning may involve removal of contaminants from the semiconductor devices (or a component thereof), and inspection may include detection of defects in the semiconductor device (or again, components thereof).

### SUMMARY

Some embodiments disclosed herein are directed to a processing chamber including an enclosure defining a processing volume, a substrate support positioned in the processing volume that is configured to support a substrate and to rotate the substrate about a central axis, and a cleaning nozzle that is configured to direct a cleaning fluid onto a surface of the substrate within the processing volume. In addition, the processing chamber includes an acoustic inspection assembly positioned in the processing volume. The acoustic inspection assembly includes a fluid nozzle that is configured to direct a stream of fluid onto the surface of the substrate. In addition, the acoustic inspection assembly includes an acoustic probe coupled to the fluid nozzle such that the acoustic probe is configured to direct an acoustic wave through the stream of fluid to detect a defect in the substrate.

Some embodiments disclosed herein are directed to a method of processing a substrate that includes directing, from a fluid nozzle of an acoustic inspection assembly, a stream of inspection fluid onto a surface of the substrate within a processing volume of a chamber. In addition, the method includes emitting, from an acoustic probe of the acoustic inspection assembly, one or more acoustic waves through the stream of inspection fluid to the surface to detect a defect in one or more regions of the substrate. Further, the method includes directing, from a cleaning nozzle, a cleaning fluid onto the surface of the substrate in the processing volume of the chamber to clean the surface.

Some embodiments disclosed herein are directed to a processing chamber including an enclosure defining a processing volume. In addition, the processing chamber includes a cleaning assembly at least partially positioned in the processing volume, wherein the cleaning assembly includes one or more nozzles that are configured to clean and dry a surface of a substrate supported in the processing volume. Further, the processing chamber includes an acoustic inspection assembly at least partially positioned in the processing volume that is configured to direct a stream of liquid inspection fluid onto the surface and to direct acoustic waves onto the surface via the stream of inspection fluid to detect a defect in a region of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of a system for performing one or more aspects of a manufacturing process (such as a packaging process) for a semiconductor device according to one or more embodiments.

FIG. 2 is a schematic side, section view of a cleaning and inspection module for use in the system of FIG. 1 according to one or more embodiments.

FIG. 3 is a schematic top, section view of the cleaning and inspection module of FIG. 2 according to one or more embodiments.

FIGS. 4 and 5 are schematic side views of an acoustic probe for use in the cleaning and inspection module of FIG. 2 performing an inspection operation according to one or more embodiments.

FIGS. 6 and 7 are top views of a semiconductor substrate illustrating different paths that an inspection assembly may take when performing an inspection operation according to one or more embodiments.

FIG. 8 is a flow diagram of a method of processing a substrate according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A semiconductor device manufacturing process may include one or more steps of cleaning and inspection to ensure the desired functionality of the formed device. For instance, cleaning and inspection steps may be performed after a bonding process, including when one or more dies or other substrates are bonded to a substrate, to ensure that the resulting electrical connections from the bond process are free of defects and contamination. Substrate-to-substrate bonding processes may be referred to herein as a “substrate bonding” processes. Conventional semiconductor device manufacturing, such as device packaging processes, involves moving the bonded substrate to multiple processing chambers that are specifically designed and configured to perform the separate inspection and cleaning steps. However, there is a continued desire to decrease and simplify the manufacturing process for a semiconductor device.

Accordingly, embodiments disclosed herein include system and methods for performing cleaning and inspection of bonded substrates in a single, integrated chamber. Use of such an integrated chamber may reduce manufacturing time and may reduce a footprint for at least some of the equipment utilized in the manufacturing process.

In some embodiments, a processing chamber may utilize a liquid-based cleaning assembly that is configured to direct a liquid onto the surface of a substrate (which may have previously been bonded to singulated dies or another substrate via a bonding process) to clean one or more surfaces of the substrate. In addition, the processing chamber may include a water jet scanning acoustic microscopy (SAM) system that is configured to direct acoustic waves through a stream of liquid inspection fluid in order to detect defects, such as defects in one or more of the previously formed bonding interfaces on the substrate. The cleaning assembly and inspection assembly may be integrated into the single processing chamber so that the separate inspection and cleaning steps may be performed without an intervening movement or transfer of the substrate between different chambers. As such, the integrated processing chamber may reduce manufacturing time and therefore increase manufacturing throughput.

In some embodiments, the cleaning and inspection assemblies of the integrated processing chamber may utilize the same (or substantially the same) liquid for cleaning and inspection purposes. As a result, the integrated processing chamber may include or be coupled to a single, common reservoir of working fluid to facilitate and support both the cleaning and inspection operations. As another example, because the cleaning and inspection assemblies may be positioned within the processing chamber, the cleaning and inspection operations may be ordered or even partially overlapped or integrated to further reduce manufacturing time.

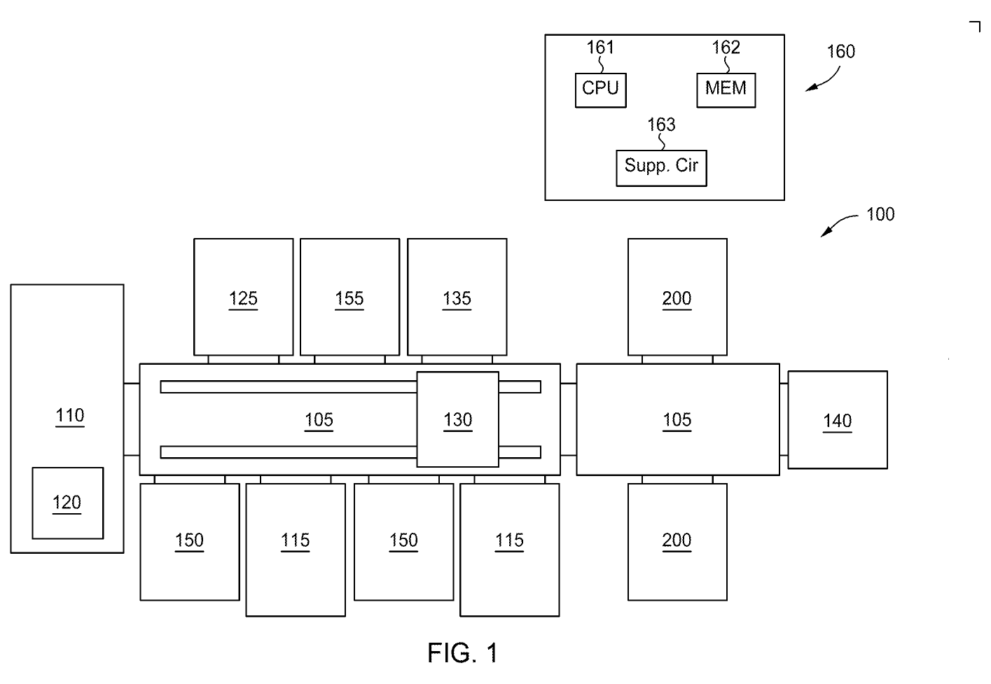

FIG. 1 is a schematic illustration of a system 100 for performing one or more aspects of a manufacturing process (such as a packaging process) for a semiconductor device according to one or more embodiments. The system 100 comprises an Equipment Front End Module (EFEM) 110 configured to load and unload substrates 120; an Automated Modular Mainframe (AMM) 130 having an integrated substrate transfer robot for transporting a substrate 120 through the system 100; a substrate aligner 105 for precisely aligning the substrate 120; one or more cleaning and inspection modules 200 for cleaning one or more surfaces of the substrate 120 and for inspecting the bonding interfaces (or more simply “bonds”) formed on the substrate 120; one or more degas modules 125 for removing absorbed moisture and contaminants from one or more surfaces of the substrate 120; one or more plasma modules 135 for activation and cleaning of one or more surfaces of the substrate 120; an ultraviolet (UV) module 140 for curing a bonding interface of the substrate 120; one or more bonder modules 150 for forming bonding interfaces on the substrate 120 (such as so to bond the substrate 120 to singulated dies or to other substrates); and one or more annealing modules 155 for annealing the substrate 120 (such as following a bonding operation in the one or more bonder modules 150). As shown in FIG. 1, in some embodiments, the system 100 may also optionally include one or more brush box cleaning modules 115 for removing residues and particles from one or more surfaces of the substrate 120. The term “substrate” may refer to a work piece, such as a semiconductor work pieces that may be bonded to one or more singulated dies or other substrates to form a semiconductor device (or a portion thereof). The term “wafer” may sometimes be used interchangeably with the term “substrate” although no difference in meaning is intended.

In some embodiments, operation of the system 100 is at least partially directed by a system controller 160. The system controller 160 (or more simply “controller” 160) includes a programmable central processing unit (CPU) 161 which is operable with a memory 162 (e.g., non-volatile memory) and support circuits 163. The support circuits 163 are coupled to the CPU 161 and comprise cache, clock circuits, input/output subsystems, power supplies, and the like, and combinations thereof coupled to the various components of the system 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the cleaning system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 160 may be used with one or any combination of the various modular polishing systems described herein and/or with the individual polishing modules thereof.

The system controller 160 may comprise a singular controller that controls one or more aspects of the operation of system 100. Conversely, in some embodiments, the system controller 160 may comprise a plurality of separate controllers that are each configured to control one or more operational aspects of one or more components (or modules) of the system 100 during operations.

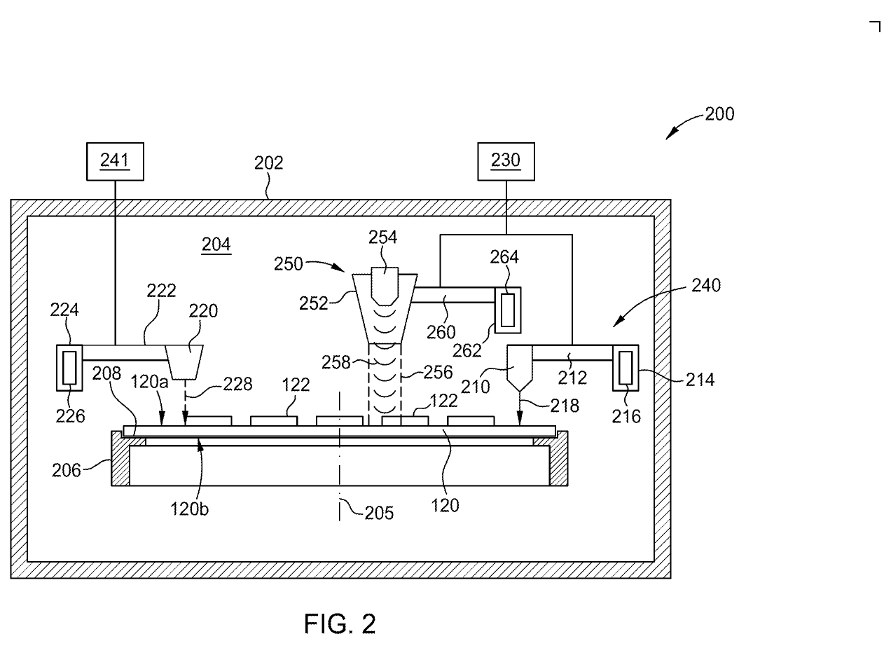

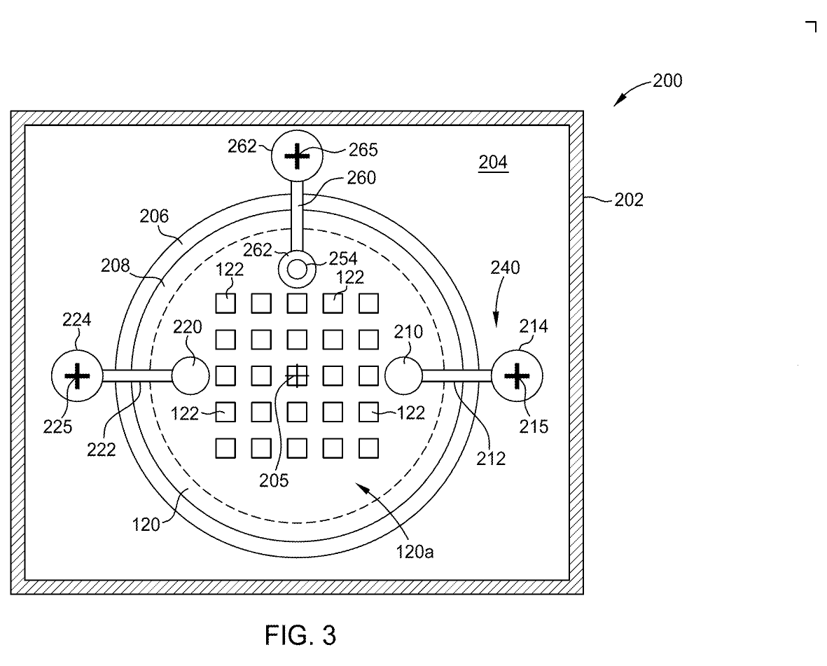

FIGS. 2 and 3 show schematic illustrations of a cleaning and inspection module 200 for use in the system 100 of FIG. 1 according to some embodiments. The cleaning and inspection module 200 may comprise a processing chamber that includes suitable assemblies for performing both cleaning and inspection operations for a substrate 120 during operations. As a result, the cleaning and inspection module 200 may be referred to herein as a cleaning and inspection processing chamber 200 or more simply a processing chamber 200.

The processing chamber 200 includes an enclosure 202 that defines a processing volume 204 therein. A substrate support 206 is positioned in the processing volume 204 to support the substrate 120. During operations, the substrate support 206 may be configured to rotate the substrate 120 about a central axis 205 within the processing volume 204. Specifically, the substrate support 206 may include or be coupled to one or more motors or other drivers (e.g., electric motor(s), hydraulic motor(s), etc. – not shown) that are configured to drive the rotation of the substrate support 206 and thus substrate 120 about central axis 205 during operations.

In addition, the substrate support 206 may be a ring-shaped structure that includes a circumferential or annular ledge 208 or other support surface (or support assembly) that is configured to support the substrate 120 within the processing volume 204. The ledge 208 exposes both a first or top surface 120a and a second or bottom surface 120b of the substrate 120. The top surface 120a may generally be a side or surface of the substrate 120 that faces axially away from the substrate support 120 (particularly the ledge 208) and the bottom surface 120b may generally be a side or surface of the substrate 120 that faces axially toward the substrate support 120 (particularly the ledge 208). Additional components or devices holding the substrate 120 to the ledge 208, such as vacuum assemblies or moveable retaining rings, may be included; however, these features are omitted in FIG. 2 in order to simplify the drawings.

A cleaning assembly 240 may be at least partially positioned in the processing volume 204. Specifically, the cleaning assembly 240 may include one or more nozzles that are configured to direct cleaning and/or drying fluids onto one or both of the surfaces 120a, 120b of the substrate 120 in order to facilitate a cleaning operation therefor. Specifically, the cleaning assembly 240 may include a cleaning nozzle 210 and a drying nozzle 220 that are positioned within the processing volume 204 and that are configured to emit a liquid cleaning fluid and a drying fluid, respectively, onto one or both of the surfaces 120a, 120b of substrate 120 during operations.

The cleaning nozzle 210 may be supported by an arm 212 that is further connected to a base 214. One or more actuators 216 may be included in or coupled to the arm 212 and/or the base 214 that are configured to facilitate movement of the cleaning nozzle 210 within the processing volume 204 relative to the substrate 120 to adjust a distance between the nozzle 210 and the substrate 120. Specifically, the one or more actuators 216 may include one or more actuators (e.g., electric motors, hydraulic motors, pneumatic motors, linear actuator(s), etc.) that are configured to move the cleaning nozzle 210 in a radially oriented plane relative to the central axis 205. The one or more actuators 216 may move the cleaning nozzle 210 in the radially oriented plane via one or both of linear or arcuate paths. In addition, the one or more actuators 216 may be configured to move the cleaning nozzle 210 in an axial direction (e.g., parallel to the central axis) relative to the substrate 120. Further, as best illustrated in FIG. 3, the one or more actuators 216 may also be configured to rotate the base 214 and thus arm 212 and cleaning nozzle 210 about an axis 215 that is parallel to (and radially offset from) the central axis 205.

The cleaning nozzle 210 may be in fluid communication with a reservoir 230 that contains a volume of liquid cleaning fluid. During operations, the liquid cleaning fluid (or more simply “cleaning fluid”) may be routed from the reservoir 230 to the cleaning nozzle 210 as the cleaning nozzle 210 is traversed across one or both of the surfaces 120a, 120b of the substrate 120 via the one or more actuators 216. Valves, pumps, and/or other fluid delivery components may be used to pressurize and deliver the cleaning fluid to the cleaning nozzle 210 from the reservoir 230 during operations; however, these additional components are not shown in FIG. 2 in order to simplify the drawings. Collection bins, pipes, or other infrastructure may collect the cleaning fluid and, after suitable filtering and treatment, deliver the cleaning fluid to a waste collection system, or deliver the collected cleaning fluid back to the reservoir 230 during operations.

The cleaning nozzle 210 may direct a stream 218 of the cleaning fluid onto a surface (such as one of the surfaces 120a, 120b) of substrate 120. In some embodiments, the cleaning fluid is selected from de-ionized water (DIW), ammonium hydroxide, hydrogen peroxide, hydrofluoric acid, sulfuric acid, or combination(s) thereof. In some embodiments, the cleaning fluid is a mixture of sulfuric acid and hydrogen peroxides. In some embodiments, the cleaning mixture is a mixture of ammonium hydroxide and hydrogen peroxide. In some embodiments, the cleaning fluid is a mixture of hydrochloric acid and hydrogen peroxide.

In some embodiments, the cleaning fluid may be heated prior to being dispensed onto substrate 120 via nozzle 210 to minimize decomposition of the cleaning chemicals. Specifically, in some embodiments, the liquid cleaning fluid emitted from cleaning nozzle 210 may comprise a heated cleaning chemical that is premixed in the reservoir 230 and heated using steam in the cleaning nozzle 210 prior to dispensing the heated cleaning fluid over the substrate 120. Without being limited to this or any other theory, preheating the chemicals in the cleaning nozzle 210 may reduce decomposition of the cleaning chemicals upon contact with the substrate and reduces the amount of chemicals used for effective cleaning. In some embodiments, nitrogen gas is injected in the cleaning nozzle 210 from a suitable source (not shown) to thereby atomize the heated cleaning fluid.

In some embodiments, acoustic cavitation, such as from megasonic energy, may be applied to the cleaning fluid while the cleaning nozzle 210 is directing the stream 218 of the cleaning fluid onto the substrate 120. The energy for inducing and maintaining the acoustic cavitation within the cleaning fluid may be applied by any suitable source, such as a back plate that is positioned in the processing volume (e.g., such as below the lower surface 120b of the substrate 120), or an acoustic source generator that is coupled to the cleaning nozzle 210 and that is configured to provide agitation to the cleaning fluid for residue and particle removal. Acoustic cavitation includes ultrasonically or megasonically energizing the fluid to dislodge residue and debris. In some embodiments, acoustically energizing fluid uses a piezoelectric transducer (PZT) operating in a frequency range from a lower ultrasonic range (e.g., about 20 KHz) to an upper megasonic range (e.g., about 2 MHz). Other frequency ranges can be used. The shape of a suitable acoustic energy source generator (e.g., a PZT) is rectangular.

The drying nozzle 220 may be supported by an arm 222 that is further connected to a base 224. One or more actuators 226 may be included in or coupled to the arm 212 and/or the base 224 that are configured to facilitate movement of the drying nozzle 220 within the processing volume 204 relative to the substrate 120. Specifically, the one or more actuators 226 may include one or more actuators (e.g., electric motors, hydraulic motors, pneumatic motors, linear actuator(s), etc.) that are configured to move the drying nozzle 220 in a radially oriented plane relative to the central axis 205. The one or more actuators 226 may move the drying nozzle 220 in the radially oriented plane via one or both of linear or arcuate paths. In addition, the one or more actuators 226 may be configured to move the drying nozzle 220 in an axial direction relative to the substrate 120 to adjust a distance between the nozzle 220 and the substrate 120. Further, as best illustrated in FIG. 3, the one or more actuators 226 may also be configured to rotate the base 224, and thus arm 222 and drying nozzle 220, about an axis 225 that is parallel to (and radially offset from) the central axis 205.

The drying nozzle 220 may be in fluid communication with a source 241 of drying fluid. In some embodiments, the drying fluid may be a gaseous fluid, such as an inert gas. For instance, in some embodiments, the drying fluid may include gaseous argon, helium, nitrogen, or combinations thereof. The source of drying fluid may be a tank, pipeline, or other system, device, or assembly that is configured to provide a flow of the drying fluid to the drying nozzle 220 during operations. During operations, the drying fluid may be routed from the source 241 to the drying nozzle 220 as the drying nozzle 220 is traversed across one or both of the surfaces 120a, 120b of the substrate 120 via the one or more actuators 226. As previously described for the cleaning nozzle 210, valves, pumps, and/or other fluid delivery components may be used to pressurize and deliver the drying fluid to the drying nozzle 220 from the source 241 during operations; however, these additional components are not shown in FIG. 2 in order to simplify the drawings.

In some embodiments, drying the substrate 120 in the processing chamber 200 includes drying using a Rotagoni process. As used herein, a “Rotagoni Process” includes pulling fluids away from the surfaces 120a,120b of the substrate 120 using a surface tension gradient formed at the mixing front between a low surface tension fluid, such as isopropyl alcohol (IPA), and a high surface tension water that are both applied to the surface of the substrate from the arm 222. The surface tension can be reduced using IPA spray or vapor, or any suitable spray or vapor that reduces surface tension of water that is dissolved therein. In some embodiments, the IPA is heated up to further reduce the surface tension of the IPA prior to applying to the substrate. In some embodiments, IPA is mixed with nitrogen to provide an IPA vapor and N₂ mixture to be dispensed over the substrate. Additionally, the Rotagoni Process and steam process used herein, quickly vaporizes the thin IPA film, that has replaced water film over the substrate using a low rotation rate of about 300 revolutions per minute (rpm) to about 500 rpm, and thus dries the cleaned substrate 120.

Referring still to FIGS. 2 and 3, an acoustic inspection assembly 250 is also positioned in the processing volume 204. As will be described in more detail herein, the acoustic inspection assembly 250 may be configured to inspect one or more bonds formed on the substrate 120 for defects, such as voids or other discontinuities formed within the substrate. Specifically, in the embodiment illustrated in FIGS. 2 and 3, a plurality of singulated dies 122 have been bonded to the upper surface 120a of substrate 120 and the inspection assembly 250 may be configured to inspect the bonds for each or some of the dies 122 during an inspection operation.

The acoustic inspection assembly 250 may include a water jet scanning acoustic microscopy (SAM) assembly that is configured to detect a presence and/or a severity of defects (such as voids or other discontinuities) in the bonding interfaces of the substrate 120 by use of acoustic energy. For instance, the acoustic inspection assembly 250 may include a fluid nozzle 252 and an acoustic probe 254 coupled to the fluid nozzle 252. The fluid nozzle 252 may be configured to direct a stream 256 of fluid (which may be referred to generally herein as “inspection fluid”) onto one of the surfaces 120a, 120b of the substrate 120 during operations. In some embodiments, the inspection fluid may be the same as the cleaning fluid that is routed to the cleaning nozzle 210. Thus, in some embodiments, the fluid nozzle 252 of acoustic inspection assembly 250 may be in fluid communication with the reservoir 230 of cleaning fluid (such as in parallel with the cleaning nozzle 210). However, it is contemplated that the inspection fluid may be different in at least some respects from the cleaning fluid provided from reservoir 230. In some embodiments, the inspection fluid may comprise DIW.

The acoustic probe 254 may be configured to generate and emit acoustic waves 258 that are conducted through a continuous stream 256 to the substrate 120 and reflected back through the continuous stream 256 from the substrate 120 to the acoustic probe 254 to facilitate inspection operations. During this process, the continuous stream 256 (or hereafter stream 256) may create a controlled environment for conducting the acoustic waves 258 to the substrate 120 from the acoustic probe 254. Thus, the stream 256 of inspection fluid may function to couple the acoustic probe 254 to the substrate 120 during the inspection operation. While a single inspection assembly 250 is shown that is configured to direct the stream 256 of inspection fluid onto the upper surface 120a of substrate 120 in FIG. 2, it should be appreciated that the inspection assembly 250 may be positioned and configured to direct the stream 256 and acoustic waves 258 upward toward the lower surface 120b through the substrate support 206. In addition, in some embodiments, a plurality of inspection assemblies 250 are included in the processing chamber 200 for directing streams 256 and acoustic waves 258 to both the upper surface 120a and the lower surface 120b as part of the inspection operation.

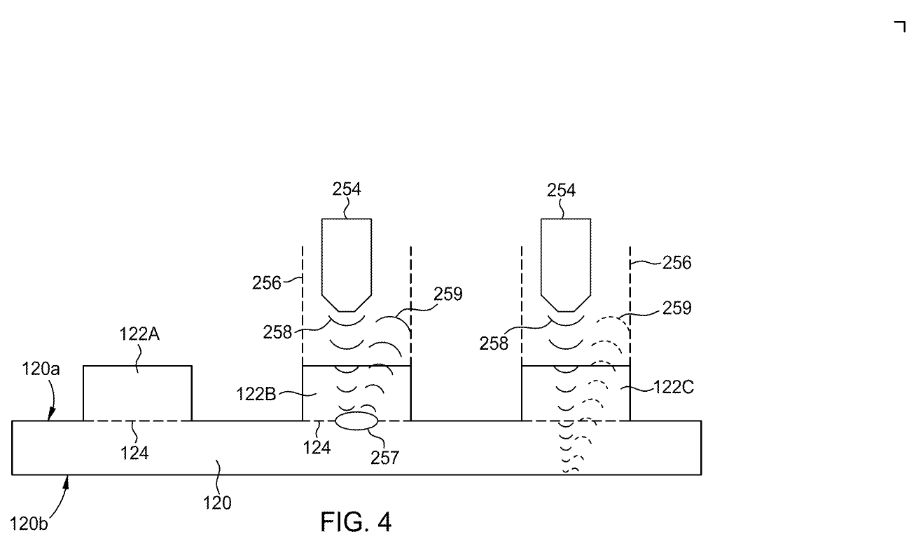

Reference is made to FIG. 4 which schematically illustrates the substrate 120 undergoing an acoustic inspection operation via the acoustic probe 254 according to some embodiments. In order to simplify the drawings, other features of the acoustic inspection device 250 and processing chamber 200 (such as the fluid nozzle 252, enclosure 202, substrate support 206, etc.) are omitted in FIG. 4.

As shown in FIG. 4, during an acoustic inspection operation, the acoustic waves 258 are emitted from the acoustic probe 254 and directed onto a surface, such as the upper surface 120a, of the substrate 120 via the stream 256 of inspection fluid. As previously described, the upper surface 120a may have a plurality of semiconductor dies (or “dies”) 122 that are bonded thereto. The dies 122 may be singulated dies and may include one or more electronic circuits, traces, or other electronic components formed therein. The dies 122 are bonded to the upper surface 120a via a bonding process, such direct placement die-to-wafer bonding, so that each die 122 is secured and electrically coupled to the upper surface 120a via a bonding interface 124. The bonding interfaces 124 may comprise areas where electrically conductive (such as metallic) terminals, traces, pads, or other surfaces or features of the dies 122 and upper surface 120a of substrate 120 are bonded (e.g., soldered, welded, fused, interconnected, etc.). FIG. 4 depicts three (3) dies 122 – labeled from left to right in the drawing as 122A, 122B, and 122C; however, the number and arrangement of the dies 122 on the upper surface 120a may be greatly varied in different embodiments.

The acoustic waves 258 travel through the stream 256 of inspection fluid and toward the dies 122 and substrate 120. The acoustic waves 258 then penetrate into the dies 122 and substrate 120 and are reflected back as reflected waves 259 that travel back to the acoustic probe 254 via the stream 256 of inspection fluid. Thus, the acoustic probe 254 may include an emitter for generating acoustic waves 258 and a sensor for detecting reflected waves 259 (or at least one or more characteristics thereof). While the reflected waves 259 are shown to be offset from the acoustic waves 258, it should be appreciated that the reflected waves 259 may travel along the same (or substantially the same) direction, axis, or path as the waves 258 during operations. Thus, the offset depiction of the reflected waves 259 in FIG. 4 is intended to make the reflected waves 259 more visible for purposes of illustration.

The acoustic probe 254 (or a sensor thereof) may be configured to detect the reflected waves 259, or at least one or more properties or characteristics thereof that may be characteristic of the condition of the bonding interfaces 124 (such as waveform, amplitude, frequency, time-of-flight, etc.). For instance, as shown for the die 122C in FIG. 4, when the bonding interface 124 is free (or substantially free) of defects (such as voids or other discontinuities), the acoustic waves 258 may generally penetrate through the bonding interface 124 and reflect off of another surface, such as the lower surface 120b of substrate 120. Conversely, as shown for the die 122B in FIG. 4, when the bonding interface 124 includes a defect 257, such as a void, the acoustic waves 258 that impact the defect 257 are reflected off of the defect 257 back to the probe 254 (as reflected waves 259) and do not penetrate through to the lower surface 120b. As a result, the reflected waves 259 off of the defect 257 are less attenuated than those that penetrate completely through the bonding interface 124 (such as to the lower surface 120b). Therefore, reflected waves 259 that are reflected back from a defect 257 in a bonding interface 124 between a die (such as die 122B) and the substrate 120 may have a “stronger” signal, in that they may have a greater amplitude, than reflected waves 259 that have penetrated deeper within the substrate 120 (that is, beyond the bonding interface 124). Accordingly, personnel and/or a controller (e.g., system controller 160 in FIG. 1) may determine a presence and/or a severity of defects 257 in a bonding interface 124 based at least in part on the “strength” (such as the amplitude) of the reflected waves 259 during an inspection operation.

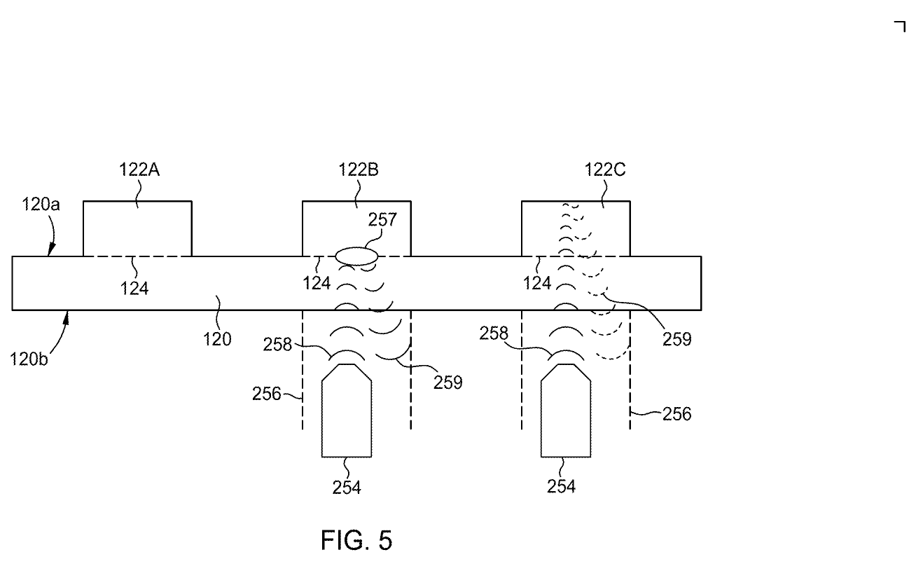

As shown in FIG. 5, in some embodiments (and as previously described), the acoustic inspection assembly 250 (FIG. 2) may be arranged so that the acoustic probe 254 directs the acoustic waves 258 toward the bottom surface 120b of the substrate 120 via the stream 256 of inspection fluid as previously described. Thus, in these embodiments, the acoustic waves 258 travel through the lower surface 120b toward the bonding interfaces 124. As shown for die 122C in FIG. 5, if the bonding interface 124 are free (or substantially free) of defects, the acoustic waves 258 may continue through the bonding interface 124 and reflect back off of another surface, such as a surface (e.g., an upper surface) of the die 122C as reflected waves 259. Conversely, as shown for die 122B in FIG. 5, if the bonding interface 124 includes a defect 257, the acoustic waves 258 that impact the defect 257 may reflect off the defect 257 and may not penetrate further into the die 122B. Accordingly, in the same manner as previously described above for FIG. 4, the reflected waves 259 that are reflected off the of the defect 257 may be less attenuated so that they include one or more characteristics that are indicative of the presence of defect 257 (such as a greater amplitude). Without being limited to this or any other theory, directing the stream 256 of inspection fluid and acoustic waves 258 toward the lower surface 120b (such as is shown in FIG. 5) may reduce the risk of damage to the dies 122 (dies 122A, 122B, 122C) caused by the direct impact of the stream 256 of inspection fluid. Moreover, in some embodiments, the delivery of the stream 256 of inspection fluid and acoustic waves 258 towards the lower surface 120b from the backside of the substrate may also provide an improved detection signal (e.g., better signal-to-noise ratio) due to the lower surface of the substrate not including dies 122 and thus avoiding any signal interference created by the surface topography created by the presence of the dies 122 as may be experienced when inspecting the substrate from above the upper surface of the substrate, as shown in FIG. 4.

In some embodiments, the frequency of the acoustic waves may be in a range of from about 10 mega Hertz (MHz) to about 500 MHz. In addition, in some embodiments, the power, such as the input power, for the acoustic waves 258 may be in a range of from about 0.01 Watts (W) to about 0.1 W. In some embodiments, the input power of the acoustic waves 258 may be less than the potential megasonic waves that may be applied when cleaning the substrate 120 via nozzle 210, which may have an input power in a range of from about 500 W to about 2000 W. Thus, the acoustic waves 258 may be configured (e.g., in their input power) to avoid cavitation in the inspection fluid during an inspection operation. Further, in some embodiments, the flow rate of the inspection fluid in the stream 256 may be in a range of from about 0.1 liters per minute (L/min) to about 1 L/min.

Referring again to FIGS. 2 and 3, the fluid nozzle 252 and acoustic probe 254 may be configured to move within the processing volume 204 relative to the substrate 120 during an inspection operation. For instance, fluid nozzle 252 and acoustic probe 254 may be supported by an arm 260 that is further connected to a base 262. One or more actuators 264 may be included in or coupled to the arm 260 and/or the base 262 that are configured to facilitate movement of the fluid nozzle 252 (and acoustic probe 254) within the processing volume 204 relative to the substrate 120. Specifically, the one or more actuators 264 may include one or more actuators (e.g., electric motors, hydraulic motors, pneumatic motors, linear actuator(s), etc.) that are configured to move the fluid nozzle 252 in a radially oriented plane relative to the central axis 205. The one or more actuators 264 may move the fluid nozzle 252 in the radially oriented plane via one or both of linear or arcuate paths. In addition, the one or more actuators 264 may be configured to move the fluid nozzle 252 in an axial direction relative to the substrate 120 to adjust a distance between the fluid nozzle 252 and the substrate 120. Further, as best illustrated in FIG. 3, the one or more actuators 264 may also be configured to rotate the base 262, and thus arm 260 and inspection assembly 250, about an axis 265 that is parallel to (and radially offset from) the central axis 205.

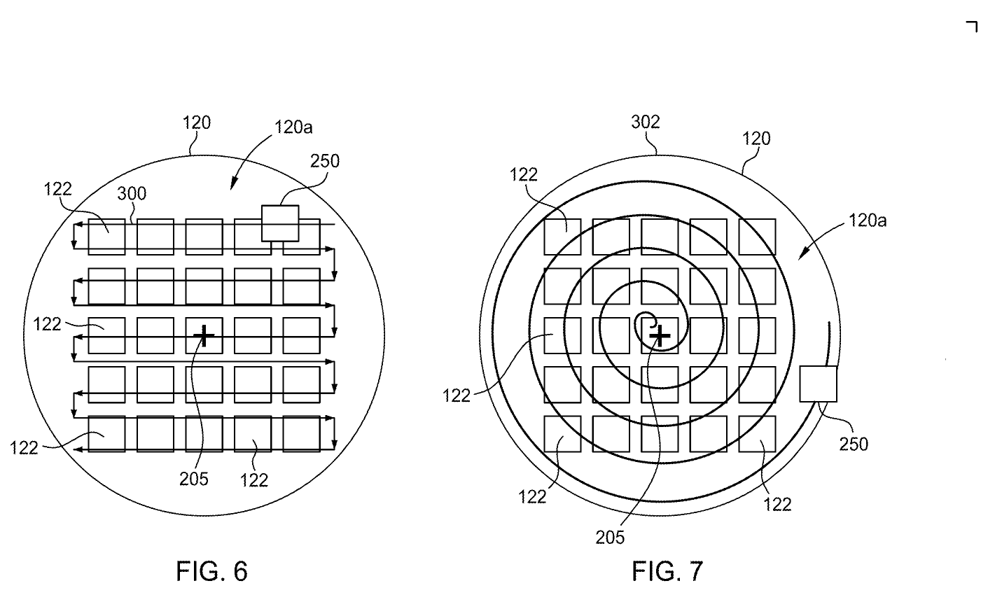

FIGS. 6 and 7 show two example paths that the inspection assembly 250 (FIG. 2) may be moved along relative to the substrate 120 in order to perform an inspection operation of the bonding interfaces 124 (FIGS. 4 and 5) of the one or more dies 122 that are bonded to the upper surface 120a of substrate 120. Specifically, as shown in FIG. 6, in some embodiments, the inspection assembly 250 may be moved along a linear path 300 in order to inspect the bonding interfaces 124 (FIGS. 4 and 5) of one or more dies 122. In some embodiments, the dies 122 may be arranged in one or more rows and columns across the upper surface 120a of substrate 120. As a result, the linear path 300 may extend linearly along one or more of the rows or columns of dies 122. In some embodiments, the linear path 300 may extend down a particular row of dies 122 in a first direction along a radially oriented plane relative to the central axis 205, and then may extend down an adjacent row of dies 122 in a second direction along the radially oriented plane that is opposite the first direction. In some embodiments, the linear path 300 may extend down all of the rows of dies 122 bonded to the upper surface 120a via switching between the first direction and second direction. In some embodiments, the linear path 300 may extend over a fraction, such as a single row or a subset of the rows, of the dies 122. The linear path 300 may be referred to as a so-called “Raster” path.

Referring briefly again to FIG. 3, the bases 214, 224, 262 may be circumferentially spaced about a perimeter of the substrate 120 relative to the central axis 205. Thus, during operation, the nozzles 210, 220 and inspection assembly 250 may be moved (e.g., via the one or more actuators 216, 226, 264, previously described) to access the exposed surface, such as the upper surface 120a or lower surface 120b, of substrate 120 during operations.

As shown in FIG. 7, in some embodiments, the inspection assembly 250 may be moved along an arcuate path 302 in order to inspect the bonding interfaces 124 (FIGS. 4 and 5) of one or more dies 122 bonded to substrate 120. Specifically, the arcuate path 302 may be shaped as a spiral that either spirals radially inward or radially outward from the central axis 205. The arcuate path 302 may be formed by coordinated movements of both the substrate 120 and the inspection assembly 250. Specifically, to form the arcuate path 302, the inspection assembly 250 may be extended radially inward toward or radially outward away from the central axis 205 (via the one or more actuators 264 in FIG. 2 as previously described), while the substrate 120 is rotated about the central axis 205 via substrate support 206 (FIG. 2) as previously described.

The linear path 300 of FIG. 6 may be beneficial for performing a higher resolution inspection of the bonding interfaces 124 (FIGS. 4 and 5) of each of the dies 122, or a subset thereof. Specifically, because the linear path 300 (FIG. 6) may be accomplished via movement of the inspection assembly 250 alone, the track and speed of the movement may be adjusted to provide higher resolution data at targeted location along the substrate 120. In addition, the linear path 300 may allow for inspection of a particular subset of the dies 122 on the substrate 120, which may be beneficial for some manufacturing processes. However, use of the linear path 300 may generally increase the time required for an inspection operation (e.g., as compared to the arcuate path 302 in FIG. 7).

Conversely, the arcuate path 302 of FIG. 7 may be beneficial for reducing the time required for an inspection operation. However, the arcuate path 302 is generally configured for an inspection of the entire upper surface 120a of the substrate 120, and may be less ideal when inspection of a subset of the dies 122 is desired.

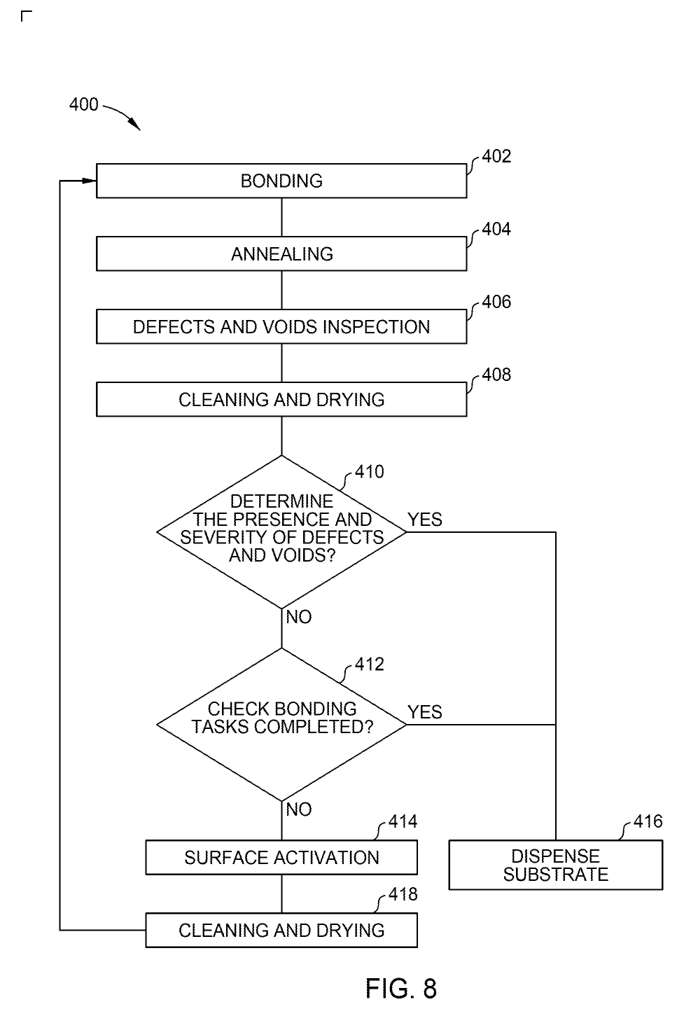

Referring now to FIG. 8, a method 400 of processing a substrate that includes at least one bond between a die and a substrate and/or between a pair of substrates is shown. In some embodiments, the method 400 may be a part of an overall method of manufacturing a device that includes the substrate (or a portion thereof). For instance, in some embodiments, the method 400 may be (or may be part of) a packaging process for a semiconductor device.

In some embodiments, the method 400 may be performed by use of the system 100 and processing chamber 200 (and related features) shown in FIGS. 1-7 and described herein. Thus, continuing reference will be made to FIGS. 1-7 when describing the features of method 400 shown in FIG. 8. However, it should be appreciated that method 400 may be performed using system and chambers that may be different in at least some respects from those shown in FIGS. 1-7 and previously described.

Initially, method 400 includes bonding at operation 402. Bonding may include the bonding of singulated dies (such as dies 122) to a substrate (such as substrate 120) or the bonding of one or more substrates to one another. The bonding may facilitate electrical connection between the bonded components (e.g., die-to-substrate, substrate-to-substrate, etc.). With respect to the system 100 shown in FIG. 1, the bonding of operation 402 may be performed at least partially in one or more of the bonder modules 150.

Following bonding in operation 402, the method 400 includes annealing the bonded substrate (that has been bonded to one or more singulated dies or another substrate as previously described) may be subjected to an annealing process at operation 404. With respect to the system 100 shown in FIG. 1, the annealing operation 404 may be performed at least partially in one or more of the annealing modules 155. Specifically, the substrate 120 may be transported to the annealing module 155 from one of the bonder modules 150 via the AMM 130 and substrate aligner 105 as previously described.

Next, method 400 includes defects and void inspection at operation 406 and wafer cleaning and drying at operation 408. As previously described, both operations 406 and 408 may be performed in a single, integrated processing chamber, such as the processing chamber 200 shown in FIGS. 2 and 3. With respect to the processing chamber 200, the defects and void inspection at operation 406 may be performed by use of the inspection assembly 250. Specifically, the inspection assembly 250 may be moved across a surface (such as the upper surface 120a and/or lower surface 120b) of the substrate 120. During this movement, the fluid nozzle 252 may be directing the stream 256 of inspection fluid onto the surface of the substrate 120, while the acoustic probe 254 is directing acoustic waves 258 through the stream 256 to contact the substrate 120 and also receiving or detecting reflected waves 259 conducted back through the fluid stream 256 (or one or more characteristics thereof) as previously described.

Also with respect to the processing chamber 200, the cleaning and drying of operation 408 may be performed by use of the cleaning assembly 240. Specifically, the cleaning nozzle 210 may be moved across a surface (such as the upper surface 120a and/or lower surface 120b) of the substrate 120 while directing the stream 218 of cleaning fluid onto the surface to dislodge debris or other contaminants. In some embodiment, acoustic energy (such as megasonic or ultrasonic energy) may be used to further dislodge debris from the surface(s) of the substrate 120. In addition, the drying nozzle 220 may also be moved across the surface (again, the upper surface 120a or lower surface 120b) of substrate 120 while directing the stream 228 of drying fluid toward the surface 120a, 120b to thereby dry the substrate 120 and thereby conclude the cleaning and drying of operation 408.

The operations 406 and 408 may be performed sequentially; however, the order of the operations 406, 408 may be varied in different embodiments. For instance, in some embodiments, the cleaning and drying operation 408 may be performed after the defects and void inspection operation 406. This order may be beneficial as it may allow the cleaning and drying operations to wash away any excess inspection fluid that may have been left on the substrate 120 following the defects and void inspection in operation 406. However, it should be appreciated that the defects and void inspection of operation 406 may be performed after the cleaning and drying operation 408 in some embodiments. Further, because the operations 406, 408 are performed in the same chamber (such as processing chamber 200) in some embodiments, the operations 406, 408 may be performed at least partially at the same time. For instance, the cleaning and drying operations 408 may be initiated before the defects and voids inspection operation 406 is completed, or vice versa.

Referring still to FIG. 8, the method 400 may also include a decision block 410, in which it is determined whether defects or voids are present on the substrate and/or the estimated severity or magnitude of any detected defects or voids. In some embodiments, the determination at decision block 410 may be at least partially performed by a computing device, such as system controller 160 shown in FIG. 1. For example, in some embodiments, the system controller 160 may receive outputs (such as output signals) from the acoustic probe 254 that may include one or more characteristics of the reflected waves 259 detected by the acoustic probe 254 during operations (e.g., amplitude). Based on these outputs, the controller 160 or personnel may determine the presence and/or severity of one or more defects (such as defect 257 shown in FIGS. 4 and 5) in one or more of the bonding interfaces 124 as previously described. Any method for detecting the presence or severity of the defects (e.g., 257) may be used including signal analysis, imaging analysis, or some combination thereof.

In some embodiments, the decision block 410 may be initiated at the same time or at an at least partially overlapping time as performance of the cleaning and drying operation 408. Thus, in some embodiments, operation 408 and decision block 410 may proceed in parallel with one another in method 400.

If defects (or defects of a threshold severity) are detected at decision block 410 (that is, the determination at decision block 410 is “yes”), the method 400 advances to operation 416 wherein the substrate 120 is dispensed from the system of process. For instance, as shown in for the system 100 in FIG. 1, operation 416 may include transporting the substrate 120 back to the EFEM 110 via AMM 130 for retrieval by personnel or other equipment. The dispensed substrate 120 may then be subjected to further repairs, analysis, destruction, or other appropriate action.

If, on the other hand, defects (or defects of the threshold severity) are not detected at decision block 410 (that is, the determination at decision block 410 is “no”), the method 400 advances to decision block 412 to determine whether the bonding tasks for the substrate have been completed. For instance, a substrate 120 may be bonded to multiple other components (including other singulated dies or other substrates as previously described) in a staged operation. That is, a substrate may be bonded to a first component in first bonding operation, and then may be bonded to a second component (or the first component may be bonded to the second component) during a second bonding operation. In some examples, stacks of components may be bonded onto a substrate, with each layered component being bonded into the stack in a separate bonding operation.

Thus, if further bonding operations are to be performed for the substate, the determination at decision block 412 is “no” and the method 400 may progress to a surface activation operation 414. The surface activation operation 414 may comprise activating (that is altering the surface energy of) the surface or component that is to be subjected to further bonding. For instance, with respect to the substrate 120 shown in FIGS. 2 and 3, if additional components are to be bonded to the dies 122, the surface activation operation 414 may include activating a surface of the dies 122 that are to be subjected to the subsequent bonding operation. With respect to the system 100 shown in FIG. 1, the surface activation operation 414 may be performed in the plasma module 135.

Following the surface activation operation 414, the substrate may be subjected to additional cleaning and drying at operation 418 in order to remove any particles or other contaminates that may have been deposited thereon. The additional cleaning and drying operation 418 may be substantially similar to the previous cleaning and drying operation 408. Thus, in some embodiments, the cleaning and drying operation 418 may be carried out in the chamber as the operation 408 (e.g., the processing chamber 200). After the additional cleaning and drying at operation 418, the method 400 recycles back to the bonding operation 402 to reinitiate the operations 402, 404, 406, 408, and decision blocks 410, 412 for the substrate with the additional component(s) bonded thereto.

If, on the other hand, further bonding operations are not to be performed for the substrate, that determination at decision block 412 is “yes” and the method 400 may progress to operation 416 wherein the substrate 120 is dispensed from the system of process as previously described.

In summary, embodiments disclosed herein include system and methods for performing cleaning and inspection of a bonded semiconductor substrate in a single, integrated chamber. Use of such an integrated chamber may reduce manufacturing time and may reduce a footprint for at least some of the equipment utilized in the manufacturing process.

In the preceding discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

While the foregoing is directed to embodiments of the present disclosure, other and further embodiments of the disclosure may be devised without departing from the basic scope thereof, and the scope thereof is determined by the claims that follow. In the claims that follow, the recitation of identifiers such as (a), (b), (c) or (1), (2), (3) before steps in a method claim are not intended to and do not specify a particular order to the steps, but rather are used to simplify subsequent reference to such steps.

What is claimed is:

1. A processing chamber comprising:
an enclosure defining a processing volume;
a substrate support positioned in the processing volume that is configured to support a substrate and to rotate the substrate about a central axis;
a cleaning nozzle that is configured to direct a cleaning fluid onto a surface of the substrate within the processing volume; and
an acoustic inspection assembly positioned in the processing volume, the acoustic inspection assembly comprising:
a fluid nozzle that is configured to direct a stream of fluid onto the surface of the substrate; and
an acoustic probe coupled to the fluid nozzle such that the acoustic probe is configured to direct an acoustic wave through the stream of fluid to detect a defect in the substrate.

2. The processing chamber of claim 1, further comprising one or more actuators that are configured to move both the cleaning nozzle and the acoustic inspection assembly in a radially oriented direction relative to the central axis to traverse the cleaning nozzle and the acoustic inspection assembly across the surface of the substrate.

3. The processing chamber of claim 2, wherein the surface of the substrate faces axially away from the substrate support along the central axis.

4. The processing chamber of claim 1, wherein the surface of the substrate faces axially toward the substrate support along the central axis.

5. The processing chamber of claim 1, wherein the cleaning nozzle and the fluid nozzle of the acoustic inspection assembly are in fluid communication with a common reservoir so that the fluid nozzle is configured to direct the cleaning fluid onto the surface of the substrate.

6. The processing chamber of claim 1, wherein the acoustic wave has a frequency in a range from about 10 mega Hertz (MHz) to about 500 MHz, and an input power in a range from about 0.01 Watts (W) to about 0.1 W.

7. The processing chamber of claim 1, wherein the processing chamber further comprises a controller that is communicatively coupled to the acoustic probe, and the controller is configured to detect an indication of a defect based at least in part on a characteristic of the reflected wave.

8. A method of processing a substrate, the method comprising:
(a) directing, from a fluid nozzle of an acoustic inspection assembly, a stream of inspection fluid onto a surface of the substrate within a processing volume of a chamber;
(b) emitting, from an acoustic probe of the acoustic inspection assembly, one or more acoustic waves through the stream of inspection fluid to the surface to detect a defect in one or more regions of the substrate; and
(c) directing, from a cleaning nozzle, a cleaning fluid onto the surface of the substrate in the processing volume of the chamber to clean the surface.

9. The method of claim 8, further comprising:
(d) traversing the acoustic inspection assembly across the surface of the substrate within the processing volume of the chamber during (a); and
(e) traversing the cleaning nozzle across the surface of the substrate within the processing volume of the chamber during (c).

10. The method of claim 9, further comprising (f) rotating the substrate during at least one of (d) and (e).

11. The method of claim 8, wherein the inspection fluid and the cleaning fluid are the same fluid, and wherein the method further comprises communicating the same fluid from a reservoir to the fluid nozzle and the cleaning nozzle.

12. The method of claim 8, further comprising:
(f) receiving a reflected acoustic wave that is reflected back through the stream of inspection fluid from the substrate; and
(g) detecting the defect based at least in part on the reflected acoustic wave.

13. The method of claim 12, wherein (g) is performed at least partially at the same time as (c).

14. The method of claim 12, further comprising:
(h) bonding one or more dies to the substrate in a first chamber;
(i) annealing the substrate in a second chamber after (h); and
(j) moving the substrate from the second chamber to the chamber after (i) and before (a) and (b).

15. The method of claim 14, wherein (h) comprise bonding the one or more dies to the surface of the substrate.

16. The method of claim 15, wherein (h) comprises bonding the one or more dies to another surface of the substrate that is opposite the surface.

17. A processing chamber comprising:
an enclosure defining a processing volume;
a cleaning assembly at least partially positioned in the processing volume, wherein the cleaning assembly includes one or more nozzles that are configured to clean and dry a surface of a substrate supported in the processing volume; and
an acoustic inspection assembly at least partially positioned in the processing volume that is configured to direct a stream of liquid inspection fluid onto the surface and to direct acoustic waves onto the surface via the stream of inspection fluid to detect a defect in a region of the substrate.

18. The processing chamber of claim 17, wherein the one or more nozzles of the cleaning assembly include:
a first nozzle that is configured to direct a liquid cleaning fluid onto the surface of the substrate; and
a second nozzle that is configured to direct a gaseous drying fluid onto the surface of the substrate.

19. The processing chamber of claim 18, wherein cleaning assembly and the acoustic inspection assembly are coupled to a fluid reservoir that holds a shared liquid fluid so that the shared liquid fluid is communicated to the first nozzle as the liquid cleaning fluid and to the acoustic inspection assembly as the liquid inspection fluid.

20. The processing chamber of claim 18, wherein the acoustic inspection assembly is configured to receive reflected acoustic waves from the substrate via the stream of inspection fluid, and further comprising a controller that is communicatively coupled to the acoustic inspection assembly that is configured to detect the defect based at least in part on the reflected acoustic wave.
